(19) United States
(12) Patent Application Publication
(10) Pub. No.: US 2018/0102390 A1
(43) Pub. Date: Apr. 12, 2018

(54) INTEGRATED IMAGING SENSOR WITH TUNABLE FABRY-PEROT INTERFEROMETER

(71) Applicant: TruTag Technologies, Inc., Kapolei, HI (US)

(72) Inventors: Hod Finkelstein, Berkeley, CA (US); Sergey Etchin, Castro Valley, CA (US)

(21) Appl. No.: 15/716,896

(22) Filed: Sep. 27, 2017

Related U.S. Application Data
(60) Provisional application No. 62/405,663, filed on Oct. 7, 2016.

(51) Int. Cl. H01L 27/146; H01L 27/148

(52) U.S. Cl. CPC H01L 27/14629; H01L 27/148; H01L 27/14643; H01L 27/14621

(57) ABSTRACT

An integrated device including a photodetector, a transparent substrate, and one or more spacers. The photodetector is formed in a portion of a wafer. The one or more spacers separate the photodetector and the transparent substrate.

### CROSS REFERENCE TO OTHER APPLICATIONS

This application claims priority to U.S. Provisional Patent Application No. 62/405,663 (Attorney Docket No. CBIOP019+) entitled INTEGRATED IMAGING SENSOR WITH TUNABLE FABRY-PEROT INTERFEROMETER filed Oct. 7, 2016 which is incorporated herein by reference for all purposes.

### BACKGROUND OF THE INVENTION

Hyperspectral imaging is of interest in many applications. Fabry-Perot Interferometers (FPI) utilize partially transmitting mirrors separated by a tunable mechanical stage. To generate a hyperspectral cube that captures the spectral content of a 2D image, an object is imaged through the FPI onto a 2D detector. In a first implementation, the FPI accepts collimated light that is then focused onto a detector. In a second implementation, the FPI is placed in the focal plane of the imaging optics. This has a number of advantages with respect to non-planarity of the FPI plates. The filtered beams are then imaged onto a photodetector. However, in order to make optimal use of the FPI it must be placed in the focal plane, whereas the photodetector also needs to be placed in the focal plane. A compromise must be made, resulting in either lower spatial resolution (photodetector off-focus) or lower spectral performance (FPI off-focus).

### BRIEF DESCRIPTION OF THE DRAWINGS

Various embodiments of the invention are disclosed in the following detailed description and the accompanying drawings.

FIG. 1A is a diagram illustrating an embodiment of a spectral imaging system.

FIG. 1B is a diagram illustrating an embodiment of a spectral imaging system including an integrated TFPI and photodetector.

FIG. 2 is a diagram illustrating an embodiment of a cross section of a silicon photodetector.

FIG. 3 is a diagram illustrating an embodiment of a silicon photodetector with a handle wafer mounted on its top side.

FIG. 4A is a diagram illustrating an embodiment of a silicon photodetector with a handle wafer and a thinned device wafer.

FIG. 4B is a diagram illustrating an embodiment of a silicon photodetector with a handle wafer and a thinned device wafer.

FIG. 4C is a diagram illustrating an embodiment of a silicon photodetector with a handle wafer and a thinned device wafer.

FIG. 4D is a diagram illustrating an embodiment of a silicon photodetector with a handle wafer and a thinned device wafer.

FIG. 4E is a diagram illustrating an embodiment of a silicon photodetector with a handle wafer and a thinned device wafer.

FIG. 5 is a diagram illustrating an embodiment of a partially reflective mirror.

FIG. 6A is a diagram illustrating an embodiment of a partially reflective mirror with patterned spacers.

FIG. 6B is a diagram illustrating an embodiment of a partially reflective mirror with patterned spacers.

FIG. 7 is a diagram illustrating an embodiment of a Fabry-Perot interferometer.

FIG. 8 is a diagram illustrating an embodiment of a Fabry-Perot interferometer including a color filter array and an anti-reflective coating.

FIG. 9 is a flow diagram illustrating an embodiment of a process for forming a Fabry-Perot interferometer.

FIG. 10 is a flow diagram illustrating an embodiment of a process for providing a device.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

An integrated imaging sensor with Fabry-Perot interferometer is disclosed. The integrated device includes a photodetector, a transparent substrate, and one or more spacers. The photodetector is formed in a portion of a wafer. The one or more spacers separate the photodetector and the transparent substrate.

An integrated imaging sensor with Fabry-Perot interferometer is disclosed. In order to fabricate a spectral imaging system with both a Fabry-Perot interferometer (FPI) and photodetector in focus in the focal plane of the imaging optics, the photodetector is integrated into the FPI. An FPI comprises two partially reflective surfaces spaced a small amount apart. The gap between the surfaces affects the optical transmissive and reflective filtering properties of the FPI. In the monolithic FPI one of the two FPI reflective surfaces is replaced by a surface of the photodetector. Typically, FPI surfaces need to have both a known and preferably controlled reflectivity (e.g., by applying a specific coating), and be very flat (e.g., typically with a surface variation that is a small fraction of the shortest wavelength of light to be detected by the interferometer). For these reasons, the front surface of complementary metal oxide semiconductor image sensors (CIS) cannot be used. Specifically, because the front surface of the CIS contains a stack of metal lines separated by dielectrics, the top surface typically has a non-planarity in the micron range. Furthermore, for this reason and because of patterning of the top surface, the reflectivity varies across the top surface of the CIS die. In recent years, backside-illuminated (B SI) CIS technologies have been commercialized whereby the back surface of the CIS wafer is processed using backgrinding, and photons impinging on the back surface of the die are absorbed in the silicon and collected and processed as before. In this scheme, the side exposed to the light is flat and unpatterned polished silicon. In some embodiments, the back surface is coated using an anti-reflective coating to reduce or control its reflectivity and used as a surface of the FPI. In various embodiments, a fixed frequency FPI and a Tunable FPI (TFPI) can be fabricated using this technique. In some embodiments, a fixed frequency FPI is formed using fixed spacers between the two FPI surfaces, and a Tunable FPI is formed using adjustable piezoelectric actuators.

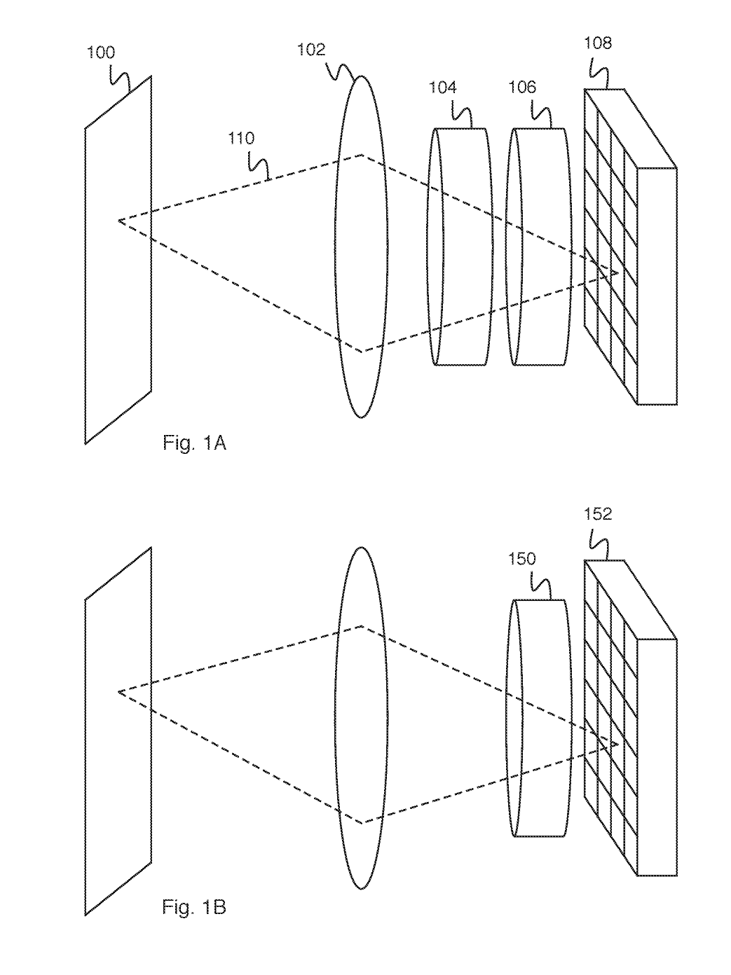

FIG. 1A is a diagram illustrating an embodiment of a spectral imaging system. In some embodiments, the diagram of FIG. 1A comprises a traditional FPI and photodetector assembly. In the example shown, light 110 comes off the surface of sample 100 (e.g., through reflection or transmission). Light 110 is focused by lens 102 and passes through an FPI comprising first FPI plate 104 and second FPI plate 106. The adjacent surfaces of first FPI plate 104 and second FPI plate 106 are partially silvered (e.g., the right surface of first FPI plate 104 and the left surface of second FPI plate 106 are coated with a thin layer of reflective material so as to reflect some light and transmit some light). After light passes through the FPI it is collected by photodetector 108. Since light cannot be in focus at both the FPI interface (e.g., at the two partially silvered surfaces) and at the photodetector surfaces, a compromise must be made. In the example shown, the photodetector is in focus and the FPI is not in focus.

FIG. 1B is a diagram illustrating an embodiment of a spectral imaging system including an integrated TFPI and photodetector. In the example shown, the TFPI of FIG. 1B comprises first FPI plate 150, which is silvered on its right side, and integrated FPI plate/photodetector 152. In some embodiments, integrated FPI plate/photodetector 152 is fabricated such that its left side meets the flatness requirement and the reflectivity uniformity. In some embodiments, integrated FPI plate/photodetector 152 is implemented using a backside-illuminated silicon photodetector.

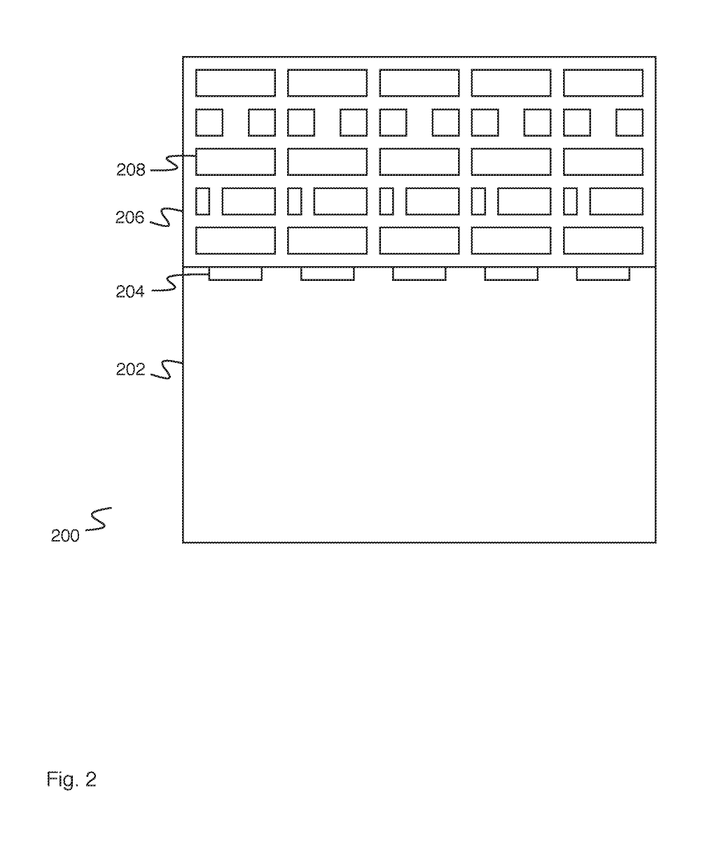

FIG. 2 is a diagram illustrating an embodiment of a cross section of a silicon photodetector. In some embodiments, silicon photodetector 200 comprises a silicon photodetector prior to being prepared for backside illumination. In the example shown, silicon photodetector comprises device wafer 202. In some embodiments, device wafer 202 comprises a single-crystal silicon wafer (e.g., a typical silicon wafer substrate for electronics fabrication). Light sensing element 204 comprises one of a plurality of light sensing elements fabricated in device wafer 202. In various embodiments, light sensing element 204 comprises a PN (e.g., P-type silicon to N-type silicon) junction, a complementary metal oxide semiconductor (e.g., CMOS) cell, a charge-coupled device (e.g., CCD), or any other appropriate light sensing element. In the example shown, the plurality of light sensing elements have a sensor element width (e.g., the lateral size of the light sensing elements). In the example shown, light sensing elements are formed in the top of device wafer 202 (e.g., such that light impinging on device wafer 202 from the backside—e.g., the bottom—does not reach the light sensing elements). Silicon photodetector 200 additionally comprises a plurality of metal lines (e.g., metal line 208) embedded in dielectric 206. In various embodiments, metal lines comprise aluminum lines, copper lines, silver lines, titanium lines, or any other appropriate lines. In various embodiments, dielectric 206 comprises silicon dioxide, stoichiometric silicon nitride, non-stoichiometric silicon nitride, or any other appropriate dielectric material. In the example shown, the top surface of silicon photodetector 200 is flat. In some embodiments, the top surface of silicon photodetector 200 is not flat (e.g., the irregularity of the metal lines telegraphs through dielectric 206 and causes irregularity at the top surface). In the example shown, the cross section of the dimension in and out of the plane of the figure is not shown in which the light sensing elements (e.g., light sensing element 204) are distributed, nor does it show the interconnection of the metal lines of silicon photodetector 200.

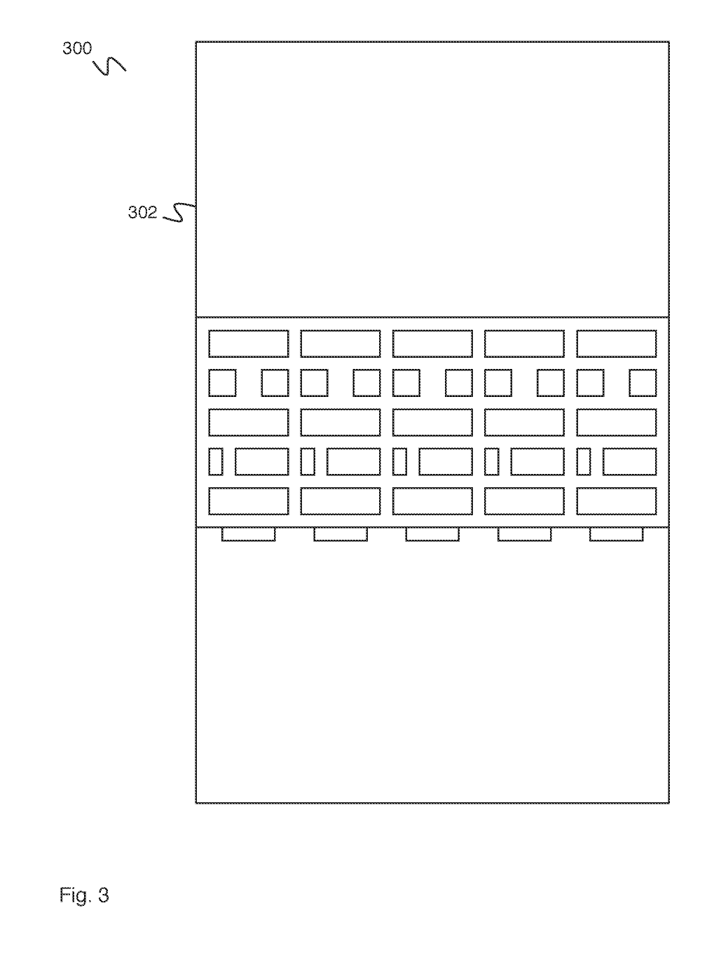

FIG. 3 is a diagram illustrating an embodiment of a silicon photodetector with a handle wafer mounted on its top side. In some embodiments, silicon photodetector 300 comprises a silicon photodetector as in silicon photodetector 200 of FIG. 2, with handle wafer 302 mounted on its top side. In various embodiments, handle wafer 302 comprises a silicon handle wafer, a glass handle wafer, an aluminum handle wafer, or any other appropriate handle wafer. In some embodiments, after handle wafer 302 is bonded to the silicon photodetector, silicon photodetector 300 can be manipulated using handle wafer 302. In some embodiments, silicon photodetector 300 is flipped over when it is handled using handle wafer 302.

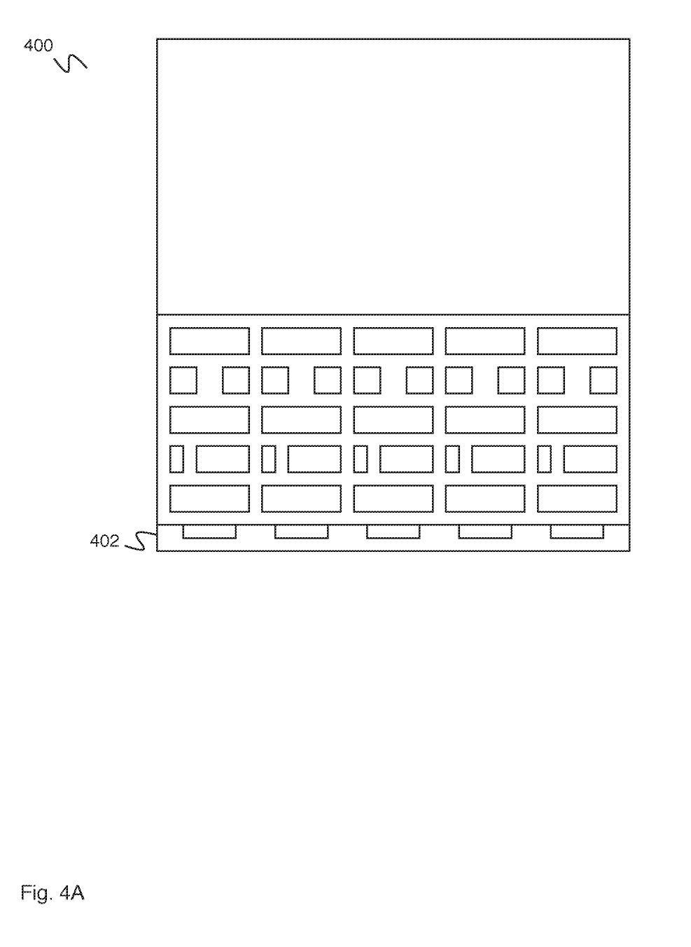

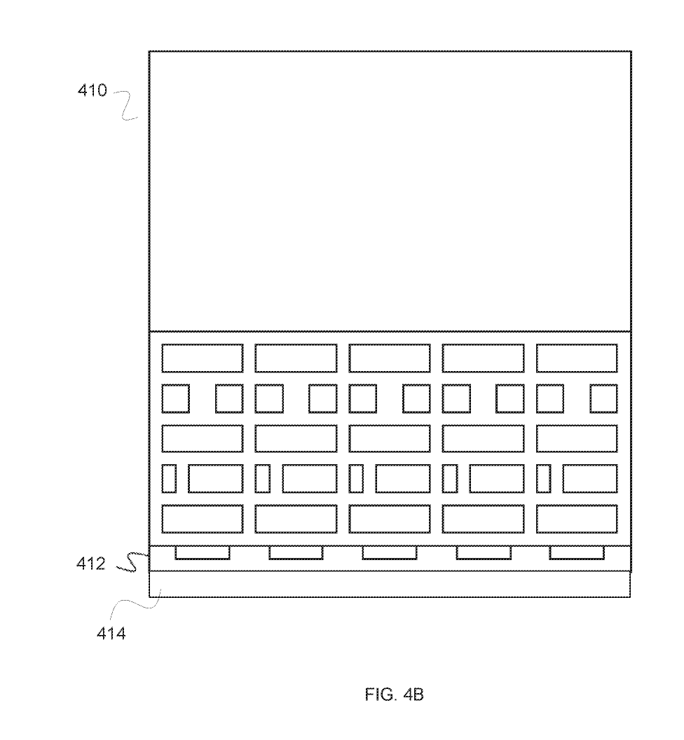

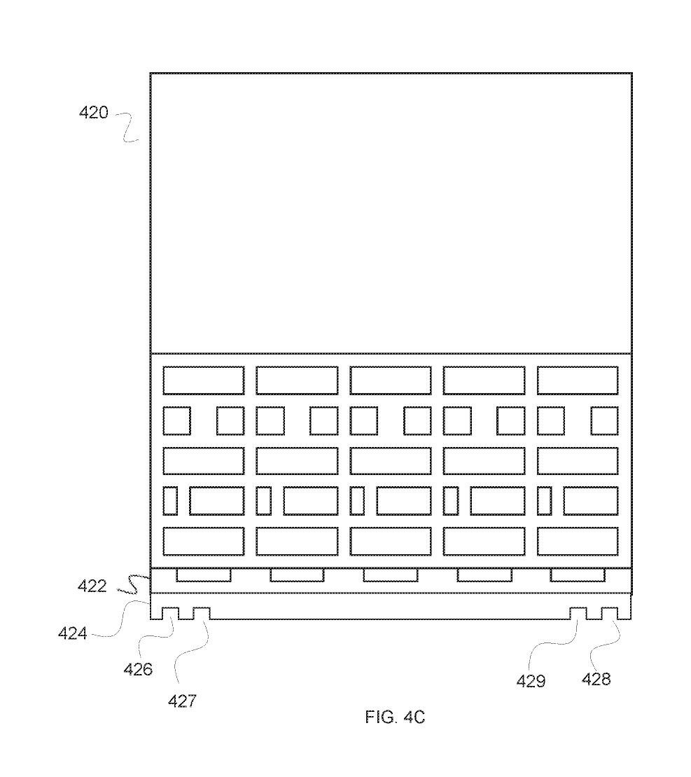

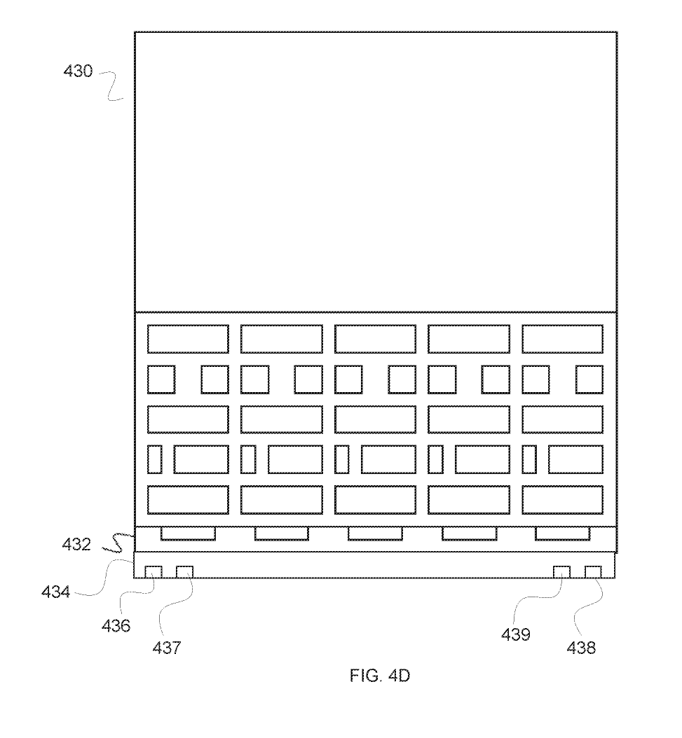

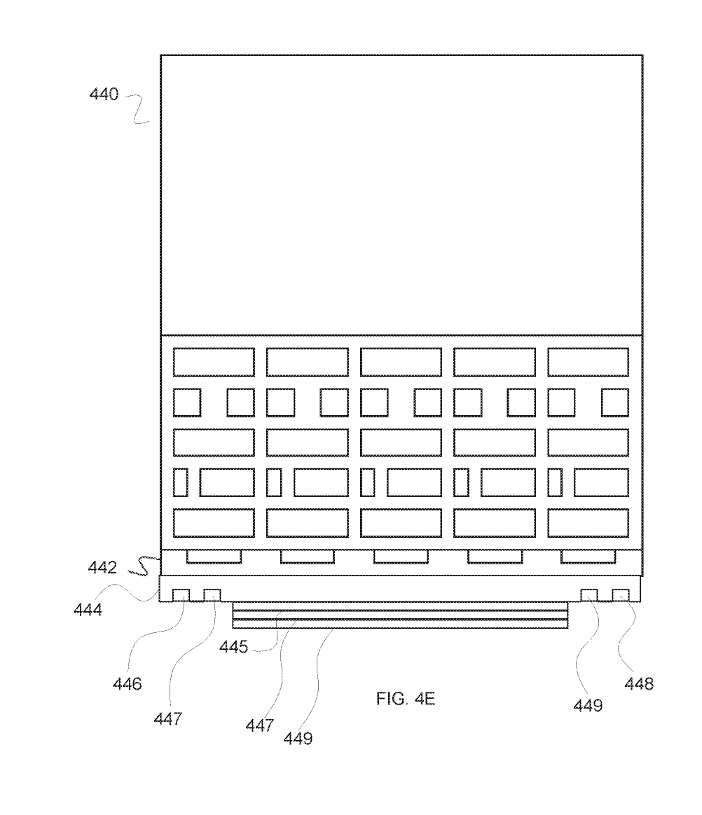

FIG. 4A is a diagram illustrating an embodiment of a silicon photodetector with a handle wafer and a thinned device wafer. In some embodiments, silicon photodetector 400 comprises silicon photodetector 300 of FIG. 3 with a thinned device wafer. In the example shown, device wafer 402 comprises a device wafer (e.g., device wafer 202 of FIG. 2) that has been thinned. In various embodiments, device wafer 402 has been thinned by grinding, etching, polishing, or any other appropriate technique. In some embodiments, silicon photodetector 400 is held by a handle wafer while device wafer 402 is thinned. In some embodiments, device wafer 402 is thinned to the point where light impinging on the backside can reach the light sensing elements at its top surface. In some embodiments, the bottom surface of device wafer 402 is polished smooth after thinning. In some embodiments, additional layers are applied to the bottom surface of device wafer 402 after thinning and polishing (e.g. a color filter, a reflective coating, an anti-reflective coating, etc.).

FIG. 4B is a diagram illustrating an embodiment of a silicon photodetector with a handle wafer and a thinned device wafer. In some embodiments, silicon photodetector 410 comprises silicon photodetector 400 of FIG. 4A with a silicon dioxide layer on the bottom. In the example shown, device wafer 412 comprises a device wafer (e.g., device wafer 202 of FIG. 2) that has been thinned and an insulating SiO₂ layer 414 is added to the bottom surface of device wafer 412.

FIG. 4C is a diagram illustrating an embodiment of a silicon photodetector with a handle wafer and a thinned device wafer. In some embodiments, silicon photodetector 420 comprises silicon photodetector 410 of FIG. 4B with a silicon dioxide layer on the bottom that has been etched. In the example shown, device wafer 422 comprises a device wafer (e.g., device wafer 202 of FIG. 2) that has been etched to produce electrode location 426, electrode location 427, electrode location 429, and electrode location 428 in SiO₂ layer 424.

FIG. 4D is a diagram illustrating an embodiment of a silicon photodetector with a handle wafer and a thinned device wafer. In some embodiments, silicon photodetector 430 comprises silicon photodetector 420 of FIG. 4C with a silicon dioxide layer on the bottom that has electrodes added. In the example shown, device wafer 432 comprises a device wafer (e.g., device wafer 202 of FIG. 2) that has metal added to produce electrode 436, electrode 437, electrode 439, and electrode 438 in SiO₂ layer 434. Electrode 436, electrode 437, electrode 439, and electrode 438 are connected electrically to the contact side of silicon photodetector 430 by through silicon vias (not shown in FIG. 4D).

FIG. 4E is a diagram illustrating an embodiment of a silicon photodetector with a handle wafer and a thinned device wafer. In some embodiments, silicon photodetector 440 comprises silicon photodetector 430 of FIG. 4D with added layers. In the example shown, device wafer 442 comprises a device wafer (e.g., device wafer 202 of FIG. 2) that has electrode 446, electrode 447, electrode 449, and electrode 448 in SiO₂ layer 444. Electrode 446, electrode 447, electrode 449, and electrode 448 are connected electrically to the contact side of silicon photodetector 430 by through silicon vias (not shown in FIG. 4E). Layers are added for creating a partially reflective surface including adhesion layer 445, metal layer 447, and passivation layer 449. The partially reflective surface comprises one plate of a Fabry-Perot interferometer.

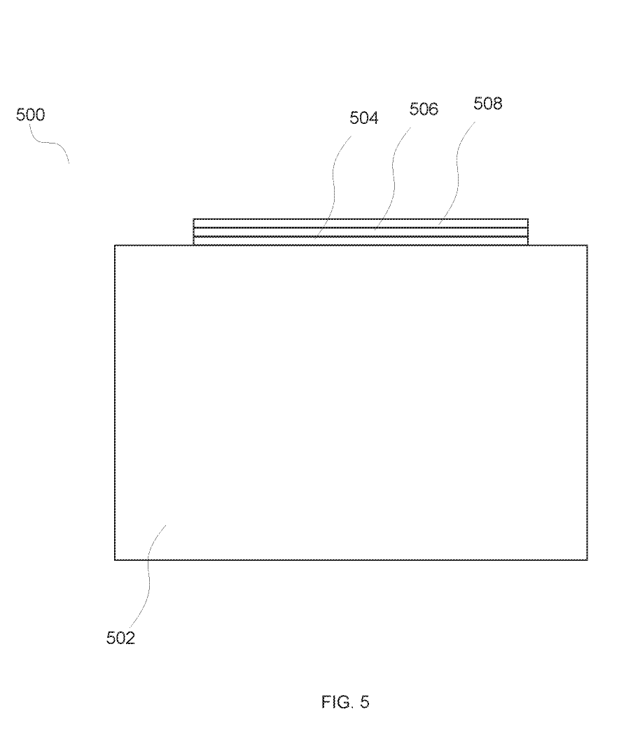

FIG. 5 is a diagram illustrating an embodiment of a partially reflective mirror. In some embodiments, partially reflective mirror 500 comprises one plate of a Fabry-Perot interferometer. In the example shown, partially reflective mirror 500 comprises transparent substrate 502 and silvering 504. In various embodiments, transparent substrate 502 comprises glass, quartz, plastic, or any other appropriate transparent substrate material. Layers are added for creating a partially reflective surface including adhesion layer 504, metal layer 506, and passivation layer 508. In various embodiments, the partially reflective surface comprises silver, aluminum, titanium, or any other appropriate thin metal film. In some embodiments, the partially reflective surface is thin enough to allow a partial transmission of light. In the example shown, the partially reflective surface uniformly coats the top side of transparent substrate 502.

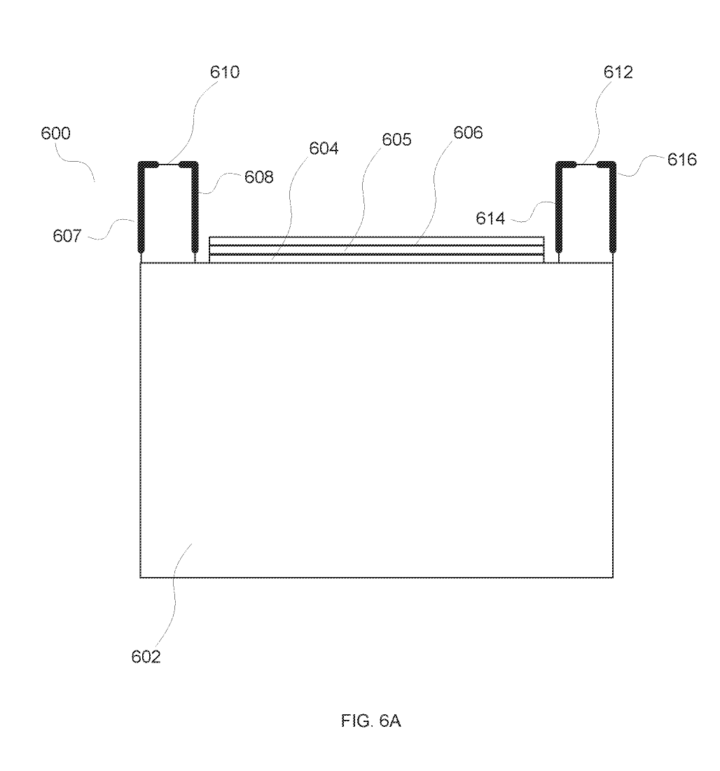

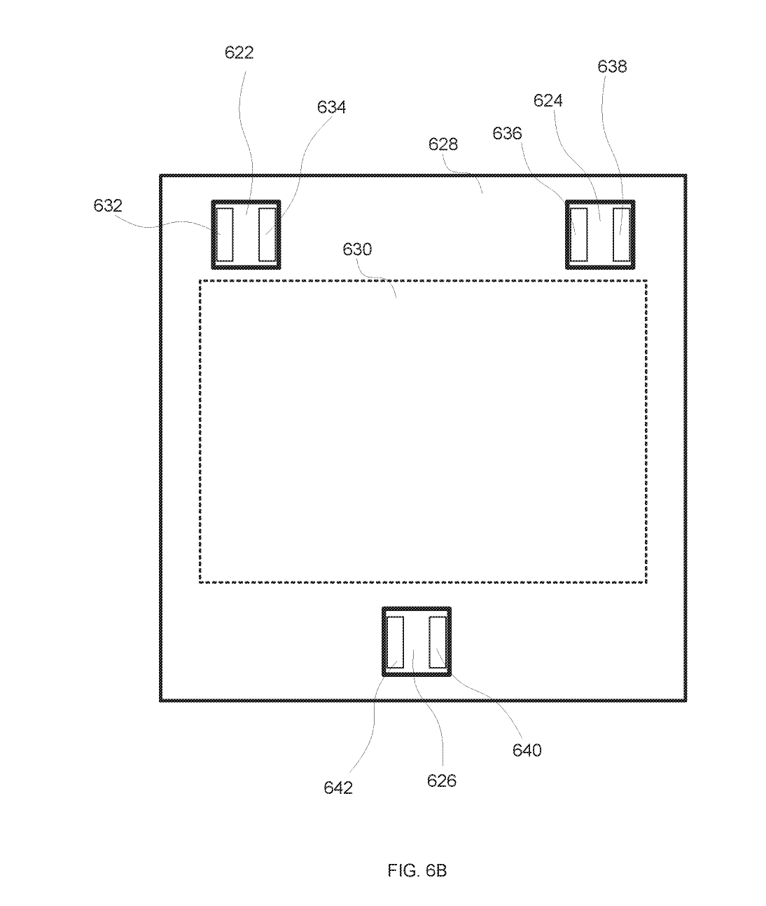

FIG. 6A is a diagram illustrating an embodiment of a partially reflective mirror with patterned spacers. In some embodiments, partially reflective mirror 600 comprises partially reflective mirror 500 of FIG. 5 with patterned spacers. In the example shown, patterned spacers (e.g., patterned spacer 610 and patterned spacer 612) are deposited on top of transparent substrate 602. In some embodiments, the patterned spacers are formed from a piezoelectric material in order to allow the spacer height to be electrically adjusted using electrodes (e.g., a height of patterned spacer 610 is adjusted using an electric signal that is applied using electrode 607 and electrode 608 and the height of patterned spacer 612 is adjusted using an electric signal using electrode 614 and electrode 616). Partially reflective surface includes adhesion layer 604, metal layer 605, and passivation layer 606.

FIG. 6B is a diagram illustrating an embodiment of a partially reflective mirror with patterned spacers. In some embodiments, partially reflective mirror 620 comprises partially reflective mirror 500 of FIG. 5 with patterned spacers. In some embodiments, the partially reflective mirror of FIG. 6B is a top view of FIG. 6A. In the example shown, patterned spacers (e.g., patterned spacer 622, patterned spacer 624 and patterned spacer 626) are deposited on top of transparent substrate 628. In some embodiments, the patterned spacers are formed from a piezoelectric material in order to allow the spacer height to be electrically adjusted using electrodes (e.g., patterned spacer 622 using electrode 632 and electrode 634, patterned spacer 624 using electrode 636 and electrode 638, and patterned spacer 626 using electrode 642 and electrode 640). The three patterned spacers enable adjusting the distance between the two mirrors as well as enabling tilt adjustment between the two mirrors. Partially reflective surface 630 includes an adhesion layer, a metal layer, and a passivation layer.

In some embodiments, the patterned spacers are not adjustable in height and form a fixed cavity for the Fabry-Perot interferometer. In various embodiments, the patterned spacers are made from silicon dioxide, silicon nitride, polyimide, or any other appropriate spacer material. In some embodiments, the patterned spacer height is determined to be similar to a sensor element width (e.g., the sensor element width of light sensors of the silicon photodetector of FIG. 2). In some embodiments, the patterned spacers are formed by depositing a uniform layer of material, polishing the layer of material, and patterning the layer of material by photolithography. In some embodiments, the patterned spacers are wafer-bonded to the partially reflective mirror. In some embodiments, the patterned spacers are formed by etching the bare transparent substrate to form trenches between spacers, then depositing the thin metal coating on the patterned substrate.

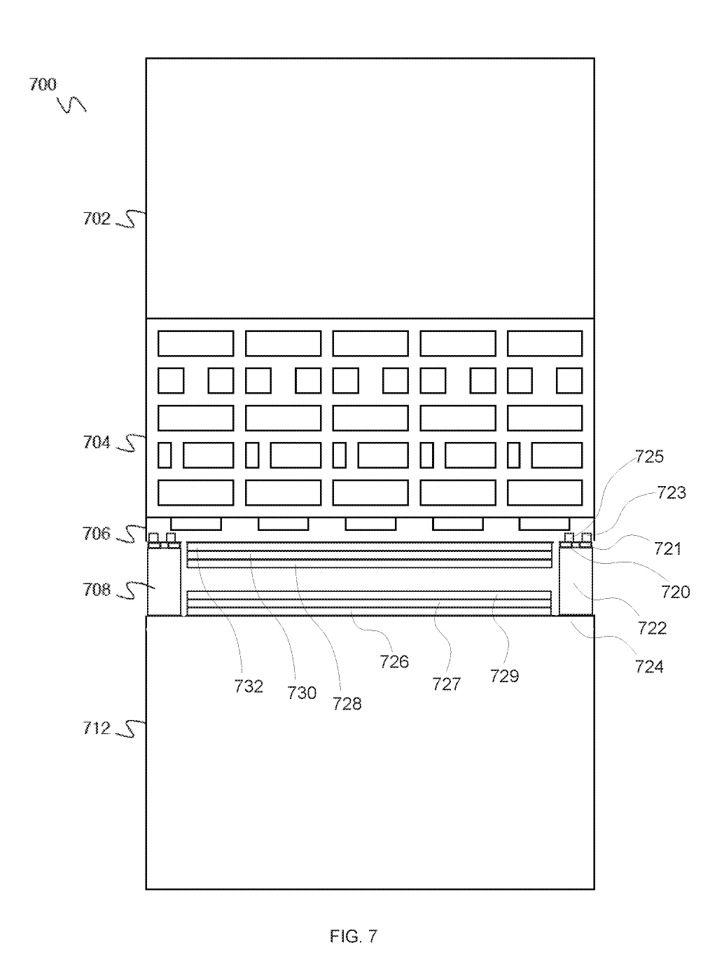

FIG. 7 is a diagram illustrating an embodiment of a Fabry-Perot interferometer. In some embodiments, Fabry-Perot interferometer 700 comprises silicon photodetector 400 of FIG. 4A bonded to partially reflective mirror 600 of FIG. 6A. In the example shown, Fabry-Perot interferometer 700 comprises handle wafer 702, dielectric with metal lines layer 704, device wafer with light sensing elements 706, patterned spacers 708, partially reflective mirror 726 and transparent substrate 712. In some embodiments, in the event patterned spacer 708 and patterned spacer 722 are formed from polyimide, the silicon photodetector is bonded to the partially reflective mirror by heating the polyimide layer while concurrently co-planarizing the substrates (e.g., the silicon photodetector and the partially reflective mirror) and cooling. In some embodiments the bottom surface of device wafer with light sensing elements 706 acts as a partially reflective mirror with adhesive layer 732, metal layer 730, and passivation layer 728 forming one plate of the interferometer; and with opposing partially reflective mirror on the top surface of transparent substrate 712. The opposing partially reflective mirror comprises adhesive layer 726, metal layer 727, and passivation layer 728 that is used to form the second plate of the interferometer. The distance between interferometer plates is set by the height of patterned spacer 708 and patterned spacer 722. In some embodiments, there are a plurality of patterned spacers used to set the distance between the partially reflective mirrors and to adjust the tilt between the partially reflective mirrors. In some embodiments, in the event the patterned spacers have an adjustable height (e.g., they are formed from a piezoelectric film), the distance between interferometer plates is adjustable (e.g., using electrode 723 and electrode 725 to provide a voltage to patterned spacer 722 via conducting adhesive 720 and conducting adhesive 721). In some embodiments, after Fabry-Perot interferometer 700 is formed, handle wafer 702 is removed and the device is handled using transparent substrate 712. In some embodiments, after the Fabry-Perot interferometer is formed, it is electrically and mechanically bonded to an electrical substrate.

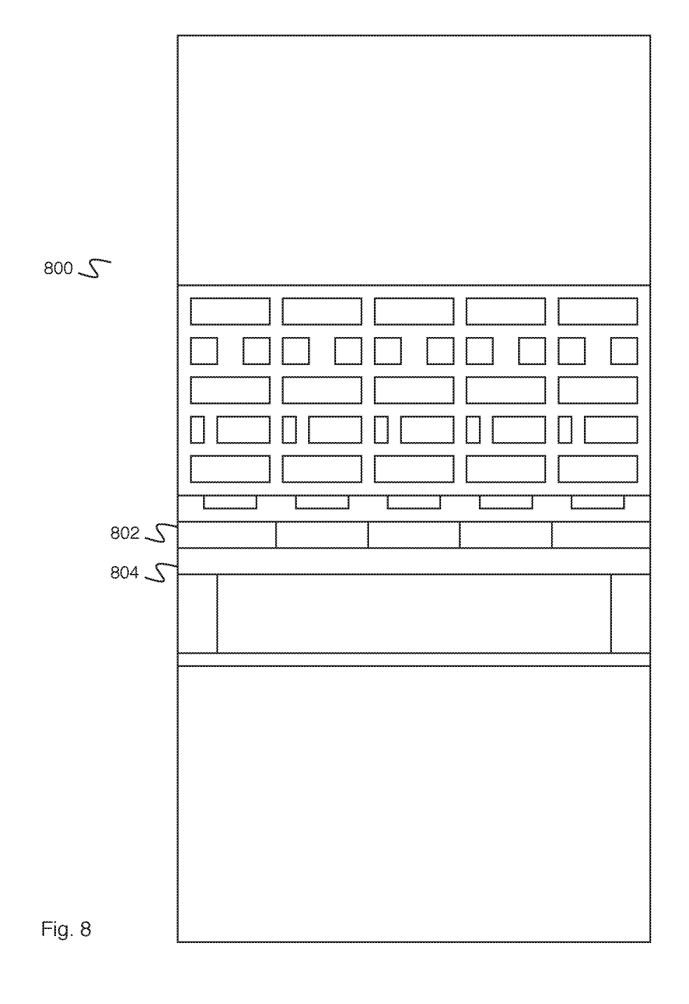

FIG. 8 is a diagram illustrating an embodiment of a Fabry-Perot interferometer including a color filter array and an anti-reflective coating. In some embodiments, Fabry-Perot interferometer 800 comprises Fabry-Perot interferometer 700 of FIG. 7 including color filter 802 and anti-reflective coating 804. In some embodiments, color filter 802 and anti-reflective coating 804 are deposited on the bottom surface of a device wafer after the device wafer is thinned and polished. In some embodiments, color filter 802 is deposited on a silvering of a partially reflective mirror on a glass substrate. In some embodiments, only one of color filter 802 and anti-reflective coating 804 is included. In the example shown, color filter 802 comprises a color filter for changing a light sensor spectral response. In some embodiments, color filter 802 comprises different colors of color filter aligned with different light sensing elements. In some embodiments, anti-reflective coating 804 comprises an anti-reflective coating to reduce the reflectivity of the bottom surface of the device wafer (e.g., only a certain amount of reflectivity is desired). In some embodiments, after the Fabry-Perot interferometer is formed, it is electrically and mechanically bonded to an electrical substrate. In some embodiments, the electrodes of FIG. 7 are also present in FIG. 8.

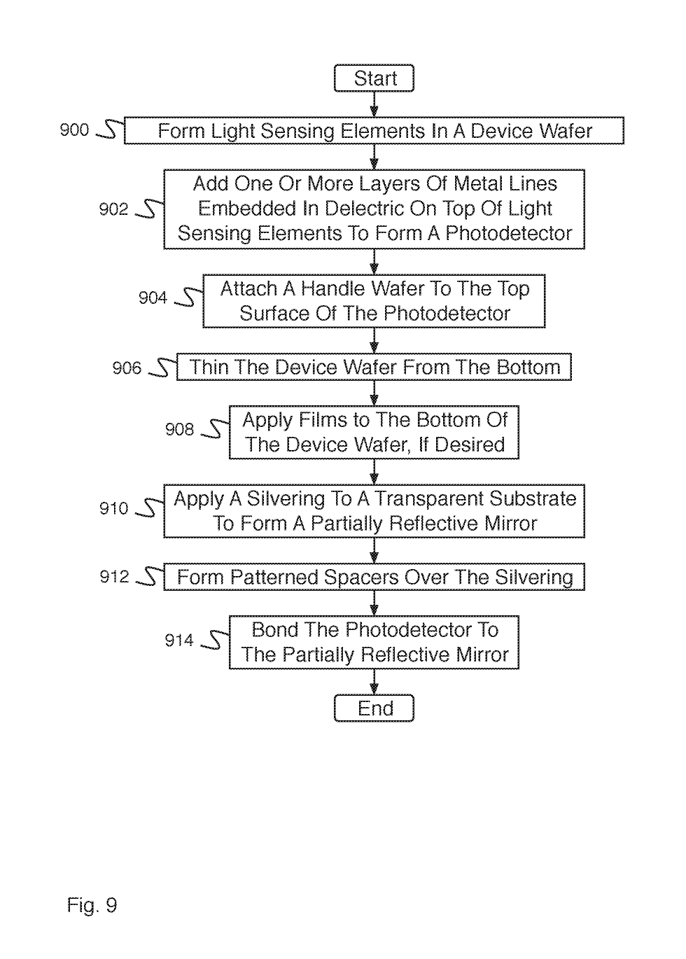

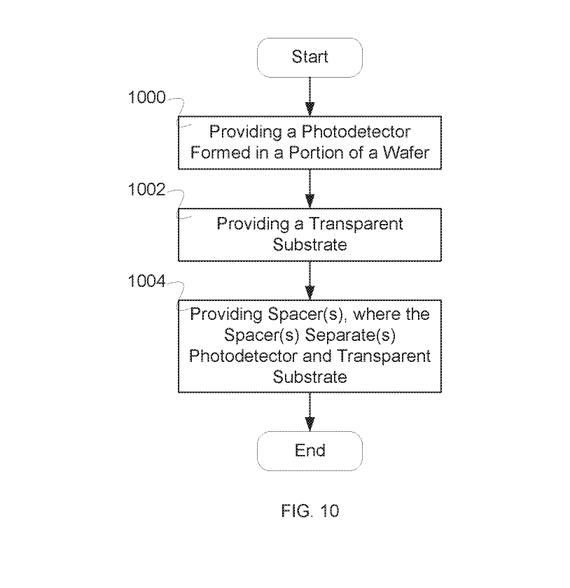

FIG. 9 is a flow diagram illustrating an embodiment of a process for forming a Fabry-Perot interferometer. In some embodiments, the process of FIG. 9 is used to form Fabry-Perot interferometer 800 of FIG. 8 or Fabry-Perot interferometer 700 of FIG. 7. In the example shown, in 900, light sensing elements are formed in a device wafer. In 902, one or more layers of metal lines embedded in dielectric are added on top of the light sensing elements to form a photodetector. For example, a photodetector is formed in a portion of a wafer. In some embodiments, the wafer is diced to form a plurality of portions of the wafer with a photodetector. In 904, a handle wafer is attached to the top surface of the photodetector. In 906, the device wafer is thinned from the bottom. In 908, films (e.g., reflective films, partially reflective films, anti-reflective films, color filtering films, etc.) are applied to the bottom of the device wafer, if desired. In 910, a silvering is applied to a transparent substrate to form a partially reflective mirror. In some embodiments, an adhesive layer is added to aid adhesion between the silvering and the substrate and a passivation layer is added to the silvering layer to aid in prevention of oxidation. In 912, patterned spacers are formed over the silvering. In some embodiments, the spacers are added over the silvering. In some embodiments, the spacers are added over an area not silvered. In 914, the photodetector is bonded to the partially reflective mirror. For example, the one or more spacers are bonded to the transparent substrate, and the one or more spacers are bonded to the photodetector. In some embodiments, bonding to the mirror comprises bonding to the spacers.

FIG. 10 is a flow diagram illustrating an embodiment of a process for providing a device. In some embodiments, the process of FIG. 10 is used to provide Fabry-Perot interferometer 800 of FIG. 8 or Fabry-Perot interferometer 700 of FIG. 7. In the example shown, in 1000 a photodetector is provided formed in a portion of a wafer. For example, a semiconductor produced photodetector is built (e.g., using PN junction, CMOS, CCD production technologies, etc.) and then processed using backgrinding to create a flat surface. This processed photodetector is part of a portion of a wafer, is separated from an entire wafer, and is provided for processing into a spectral imaging device. In some embodiments, a handling wafer is attached to the top surface of the photodetector for handling of the thinner background photodetector for stability during and/or after processing. In 1002, a transparent substrate is provided. For example, a glass, a quartz, a plastic, or any other appropriate transparent substrate material (e.g., transparent in the spectral range of interest for the device) is provided to be part of the device that comprises one surface of a Fabry-Perot etalon along with the now flat backside of the photodetector. The backside of the photodetector and the surface of the transparent substrate may be coated to provide appropriate reflectivity characteristics (e.g., reflective coating(s), anti-reflective coating(s), color selective coating(s), metal coating(s), etc.) to achieve desired Fabry-Perot etalon performance. In 1004, spacer(s) is/are provided, wherein the spacer(s) separate(s) the photodetector and transparent substrate. For example, the flat background backside of the photodetector is spaced from the transparent substrate using one or more spacers to create a Fabry-Perot etalon. The etalon filters light that enters through the transparent substrate, reaches the backside of the photodetector, and is detected using the photodetector. In some embodiments, the spacers are actuators capable of adjusting the distance between the surfaces of the backside of the photodetector and the transparent surface to provide tuning of the filter and/or parallelizing or tilting of the surface with respect to each other. In some cases, three actuators are used for controlling the respective tilting between the photodetector and the transparent surface. In various embodiments, the actuators are piezoelectric and are controlled electrically using electrodes that are connected via the portion of the wafer that has the photodetector or via the surface of the transparent substrate.

In some embodiments, the device is placed in a package that is sealed but allows access for the light to be measured and for the electric signals to be sent to and from the device.

Semiconductor processing for the device enables the entire device to be compact and ultimately lower cost than large scale versions. The device also enables the Fabry-Perot etalon to be in the same optical plane as the detector offering design flexibility for an instrument incorporating the device.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. An integrated device, comprising:
a photodetector formed in a portion of a wafer;
a transparent substrate; and
one or more spacers, wherein the one or more spacers separate the photodetector and the transparent substrate.

2. The integrated device as in claim 1, wherein the one or more spacers are bonded to the transparent substrate.

3. The integrated device as in claim 1, wherein the one or more spacers are bonded to the photodetector.

4. The integrated device as in claim 1, wherein the transparent substrate is silver coated.

5. The integrated device as in claim 1, wherein the photodetector includes light sensing elements.

6. The integrated device as in claim 5, wherein the light sensing elements comprise one of the following: a PN junction, a complementary metal oxide semiconductor, or a charge coupled device.

7. The integrated device as in claim 1, wherein the photodetector includes metal lines.

8. The integrated device as in claim 1, wherein a handle wafer is attached to the photodetector.

9. The integrated device as in claim 8, wherein the handle wafer comprises one of the following: a silicon handle wafer, a glass handle wafer, or an aluminum wafer.

10. The integrated device as in claim 1, wherein the wafer is thinned on a side.

11. The integrated device as in claim 10, wherein one or more films are applied to the wafer on the side that was thinned.

12. The integrated device as in claim 11, wherein the one or more films comprise one or more of the following: a reflective film, a partially reflective film, an anti-reflective film, or a color filtering film.

13. The integrated device as in claim 10, wherein the wafer is thinned by grinding, etching, or polishing.

14. The integrated device as in claim 1, wherein the one or more spacers are made from silicon dioxide, silicon nitride, or polyimide.

15. The integrated device as in claim 1, wherein the one or more spacers are made from a piezoelectric material.

16. The integrated device as in claim 1, wherein a spacer height is able to be adjusted by applying an electric signal to the piezoelectric material via electrodes.

17. A method for manufacture of an integrated device, comprising:
providing a photodetector formed in a portion of a wafer;
providing a transparent substrate; and
providing one or more spacers, wherein the one or more spacers separate the photodetector and the transparent substrate.
